(19) United States
(12) Patent Application Publication
(10) Pub. No.: US 2018/0240910 A1
(43) Pub. Date: Aug. 23, 2018

(54) TRANSISTOR, DISPLAY DEVICE HAVING THE SAME AND METHOD OF MANUFACTURING TRANSISTOR

(71) Applicant: SAMSUNG DISPLAY CO., LTD., Yongin-si (KR)

(72) Inventors: Yoon Ho KHANG, Yongin-si (KR); Doo Na KIM, Yongin-si (KR); Myoung Geun CHA, Yongin-si (KR)

(21) Appl. No.: 15/901,137

(22) Filed: Feb. 21, 2018

(30) Foreign Application Priority Data
Feb. 22, 2017 (KR) 10-2017-0023641

(51) Int. Cl. H01L 29/786; H01L 21/3115; H01L 29/66

(52) U.S. Cl. CPC H01L 29/78603; H01L 27/1218; H01L 29/66757; H01L 21/31155

(57) ABSTRACT

A transistor includes a buffer layer, an active pattern, and a first insulating layer. The buffer layer is doped with an impurity. The active pattern is on the buffer layer and includes a channel area between a source area and a drain area. The first insulating layer is on the active pattern. A gate electrode is on the first insulating layer and overlaps the channel area. A source electrode is insulated from the gate electrode and is electrically coupled with the source area. A drain electrode is insulated from the gate electrode and is electrically coupled with the drain area.

### CROSS-REFERENCE TO RELATED APPLICATION

Korean patent application no. 10-2017-0023641 filed on Feb. 22, 2017, and entitled, “Transistor, Display Device Having the Same and Method of Manufacturing Transistor,” is incorporated by reference herein in its entirety.

### BACKGROUND

### 1. Field

One or more embodiments described herein relate to a transistor, a display device having a transistor, and a method for manufacturing a transistor.

### 2. Description of the Related Art

Many electronic products have a display device. Examples include televisions, cellular phones, tablet computers, navigation apparatuses, and game consoles. One type of display device that is often found in these products is an organic light-emitting diode (OLED) device. This type of display device is self-emissive and has a wide viewing angle, excellent contrast, and high response speed.

An OLED device has pixels that emit light using organic light-emitting diodes. The diodes emit light based on current controlled by driving transistors in the pixels. The current controlled by the driving transistors corresponds to voltages stored in capacitors in the pixels.

### SUMMARY

In accordance with one or more embodiments, a transistor includes a buffer layer on a substrate and doped with an impurity; an active pattern on the buffer layer and including a channel area between a source area and a drain area; a first insulating layer on the active pattern; a gate electrode on the first insulating layer and overlapping the channel area; a source electrode insulated from the gate electrode and electrically coupled with the source area; and a drain electrode insulated from the gate electrode and electrically coupled with the drain area.

The active pattern may be doped with an impurity of a first conductivity type, and the buffer layer may be doped with an impurity of a second conductivity type opposite to the first conductivity type. A change in a threshold voltage of the transistor may increase as a dose of the impurity of the first conductivity type increases. A doping concentration of each of the source area and the drain area may be greater than a doping concentration of the channel area.

In accordance with one or more other embodiments, a method for manufacturing a transistor includes forming a buffer layer and a semiconductor layer on a substrate; performing a first doping process of doping the semiconductor layer with a first impurity; performing a second doping process of doping the buffer layer with a second impurity; forming an active pattern by patterning the semiconductor layer; forming a first insulating layer on the active pattern; forming a gate electrode on the first insulating layer; and performing a third doping process of forming a source area and a drain area by doping a portion of the active pattern with a third impurity using the gate electrode as a mask. The buffer layer may be between the substrate and active pattern.

The first impurity may be of a first conductivity type, and the first doping process may include accelerating the first impurity with a first energy to be implanted in the active pattern. The second impurity may be accelerated with a second energy to be implanted in the active pattern, and the second energy may be greater than the first energy. The second impurity may be of a second conductivity type opposite to the first conductivity type.

The method may include annealing the semiconductor layer and the buffer layer after the second doping process. The annealing may be performed using an excimer laser. The method may include forming a source electrode coupled to the source area and a drain electrode coupled to the drain area. A dose of the third impurity may be greater than a dose of an impurity of a channel area between the source area and the drain area.

In accordance with one or more other embodiments, a display device includes a display panel including a plurality of pixels on a substrate, wherein each of the pixels includes an electrode, a display layer on the electrode, and a transistor coupled to the electrode, and wherein the transistor includes: a buffer layer on the substrate and doped with an impurity; an active pattern on the buffer layer and including a channel area between a source area and a drain area; a gate electrode insulated from the active pattern and overlapping the channel area; and a source electrode and a drain electrode insulated from the gate electrode and respectively electrically coupled to the source area and the drain area. The channel area may be doped with an impurity of a first conductivity type, and the buffer layer may be doped with an impurity of a second conductivity type opposite to the first conductivity type. The transistor may be a PMOS transistor, and the impurity of the first conductivity type may be a p-type impurity.

In accordance with one or more other embodiments, a transistor includes a buffer layer doped with an impurity of a first conductivity type; and an active pattern on the buffer layer and doped with an impurity of a second conductivity type, wherein the active pattern includes a channel area between a source area and a drain area and wherein each of the source area and drain have a first doping concentration of the impurity of the second conductivity type greater than a second doping concentration of the impurity of the second conductivity type of the channel area. A threshold voltage of the transistor may be proportional to the first doping concentration of the impurity of the second conductivity type. The transistor may be a PMOS transistor, and the impurity of the first conductivity type may be a p-type impurity. A doping concentration of the impurity of the first conductivity type in the buffer layer may be equal to or greater than at least one of the first doping concentration and the second doping concentration.

### BRIEF DESCRIPTION OF THE DRAWINGS

Features will become apparent to those of skill in the art by describing in detail exemplary embodiments with reference to the attached drawings in which:

FIG. 1 illustrates an embodiment of an organic light-emitting diode device;

FIG. 2 illustrates an embodiment of a pixel;

FIG. 3 illustrates a layout embodiment of the pixel;

FIG. 4 illustrates a sectional view taken along line I-I′ in FIG. 3;

FIGS. 5 to 10 illustrate stages corresponding to an embodiment of a method for manufacturing a transistor;

FIG. 11 illustrates an embodiment of a transistor; and

FIGS. 12A and 12B illustrate examples of differences in hysteresis characteristics of the transistor depending on whether or not a buffer layer is doped.

### DETAILED DESCRIPTION

Example embodiments are described with reference to the drawings; however, they may be embodied in different forms and should not be construed as limited to the embodiments set forth herein. Rather, these embodiments are provided so that this disclosure will be thorough and complete, and will convey exemplary implementations to those skilled in the art. The embodiments (or portions thereof) may be combined to form additional embodiments

In the drawings, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

When an element is referred to as being “connected” or “coupled” to another element, it can be directly connected or coupled to the another element or be indirectly connected or coupled to the another element with one or more intervening elements interposed therebetween. In addition, when an element is referred to as “including” a component, this indicates that the element may further include another component instead of excluding another component unless there is different disclosure.

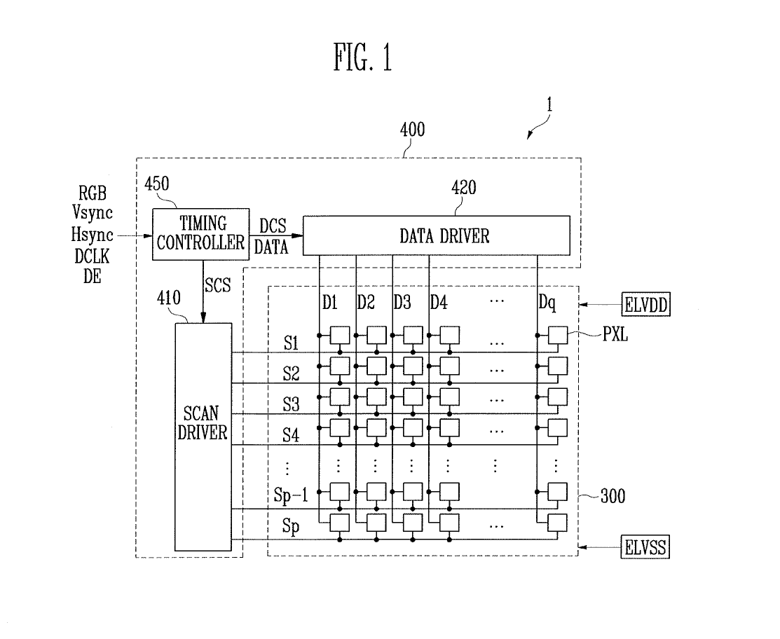

FIG. 1 illustrates an embodiment of an OLED device 1 which may include a display panel 300 and a display drive unit 400. The display panel 300 has data lines D1 to Dq and scan lines S1 to Sp coupled to pixels PXL. The pixels PXL are supplied with data signals and scan signals through the corresponding ones of the data lines D1 to Dq and scan lines S1 to Sp. The pixels PXL may be coupled to a first power source ELVDD and a second power source ELVSS.

Each pixel PXL may include a light-emitting element (e.g., an OLED) and generates light corresponding to a data signal based on current flowing from the first power source ELVDD to the second power source ELVSS, via the light-emitting element.

The display drive unit 400 may include a scan driver 410, a data driver 420, and a timing controller 450. The scan driver 410 may supply scan signals to the scan lines S1 to Sp based on a scan driver control signal SCS. The scan driver 410 may, for example, successively supply scan signals to the scan lines S1 to Sp. The scan driver 410 is connected to the scan lines S1 to Sp and may be directly mounted on a substrate 110 that includes the pixels PXL. In one embodiment, the scan driver 410 may be coupled to the substrate 110 by a separate component, e.g., a flexible circuit board.

The data driver 420 may receive a data driver control signal DCS and image data DATA from the timing controller 450 and generate data signals. The data driver 420 may supply the data signals to the data lines D1 to Dq. The data driver 420 is connected to the data lines D1 to Dq and may be directly mounted on the substrate 110 including the pixels PXL. In one embodiment, the data driver 420 may be coupled with the substrate 110 by a separate component such as a flexible circuit board.

When a scan signal is supplied to a scan line, pixels PXL coupled to the scan line may receive data signals from corresponding ones of the data lines D1 to Dq. The pixels PXL corresponding to the scan line emit light with brightnesses that correspond to the data signals.

The timing controller 450 may generate control signals for controlling the scan driver 410 and the data driver 420. For example, the control signals may include a scan driver control signal SCS for controlling the scan driver 410 and a data driver control signal DCS for controlling the data driver 420.

The timing controller 450 may generate the scan driver control signal SCS and the data driver control signal DCS based on an external input signal. The external input signal may include, for example, a dot clock DCLK, a data enable signal DE, a vertical synchronization signal Vsync, and a horizontal synchronization signal Hsync. The timing controller 450 may provide the scan driver control signal SCS to the scan driver 410 and the data driver control signal DCS to the data driver 420.

The timing controller 450 may translate image data RGB input from an external device into image data DATA corresponding to the specifications of the data driver 420. The image data DATA is then supplied to the data driver 420.

The data enable signal DE may define a period in which valid data is input. One cycle may be set as one horizontal period equal to that of the horizontal synchronization signal Hsync.

In FIG. 1, the scan driver 410, the data driver 420, and the timing controller 450 are separately provided. In one embodiment, two or more of the scan driver 410, the data driver 420, and the timing controller 450 may be integrated, e.g., in a single chip. The scan driver 410, the data driver 420, and the timing controller 450 may be provided in, for example, a chip-on-glass form, a chip-on-plastic form, a tape carrier package form, or a chip-on-film form.

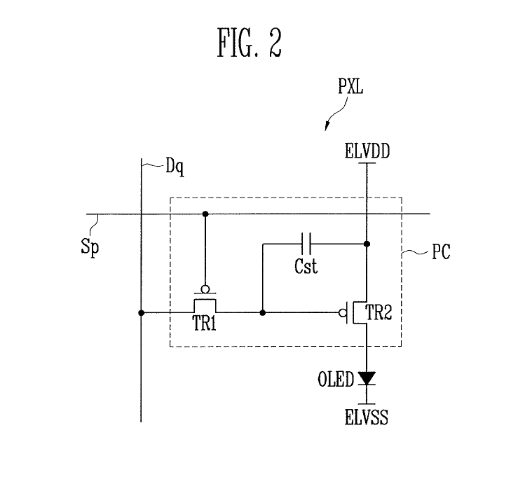

FIG. 2 illustrates an equivalent circuit embodiment of a pixel, which, for example, may be representative of the pixels PXL in FIG. 1. For the sake of explanation, a pixel PXL coupled to a p-th scan line Sp and a q-th data line Dq is illustrated.

Referring to FIG. 2, the pixel PXL may include a pixel circuit PC for controlling an organic light-emitting diode OLED. The pixel circuit PC is coupled to the q-th data line Dq and the p-th scanning line Sp. The organic light-emitting diode OLED coupled to the pixel circuit PC and a cathode electrode coupled to the second power source ELVSS. The organic light-emitting diode OLED may emit light having a predetermined luminance corresponding to current supplied from the pixel circuit PC.

The pixel circuit PC may store a data signal to be supplied to the q-th data line Dq when a scan signal is supplied from the p-th scan line Sp. The pixel circuit PC may control current to be supplied to the organic light-emitting diode OLED based on the stored data signal.

In an embodiment, the pixel circuit PC may include a first transistor TR1, a second transistor TR2, and a storage capacitor Cst. The first transistor TR1 may be coupled between the q-th data line Dq and the second transistor TR2. The first transistor TR1 has a gate electrode coupled to the p-th scan line Sp, a first electrode coupled to the q-th data line Dq, and a second electrode coupled to a gate electrode of the second transistor TR2.

When a scan signal is supplied from the p-th scan line Sp, the first transistor TR1 is turned on. As a result, a data signal is supplied from the q-th data line Dq to the storage capacitor Cst. The storage capacitor Cst may charge a voltage corresponding to the data signal.

The second transistor TR2 may be coupled between the first power source ELVDD and the organic light-emitting diode OLED. In an embodiment, the second transistor TR2 has a gate electrode coupled both to a first electrode of the storage capacitor Cst and to the second electrode of the first transistor TR1, a first electrode coupled both to a second electrode of the storage capacitor Cst and to the first power source ELVDD, and a second electrode coupled to the anode electrode of the organic light-emitting diode OLED.

The second transistor TR2 may function as a driving transistor to control current lowing from the first power source ELVDD to the second power source ELVSS, via the organic light-emitting diode OLED, in correspondence with a voltage stored in the storage capacitor Cst. The organic light-emitting diode OLED generates light corresponding to current supplied from the second transistor TR2.

The first electrode of each transistor TR1, TR2 may be one of a source electrode or a drain electrode. The second electrode of each transistor TR1, TR2 may be the other of the source electrode or the drain electrode. For example, if the first electrode is a source electrode, the second electrode may be a drain electrode. In FIG. 2, the transistors TR1 and TR2 are PMOS transistors, but one or both of the transistors TR1 and TR2 may be NMOS transistors in another embodiment.

The first power source ELVDD may have a high potential voltage, and the second power source ELVSS may have a low potential voltage. In one embodiment, the first power source ELVDD may be set to a positive voltage and the second power source ELVSS may be set to a negative voltage or ground voltage.

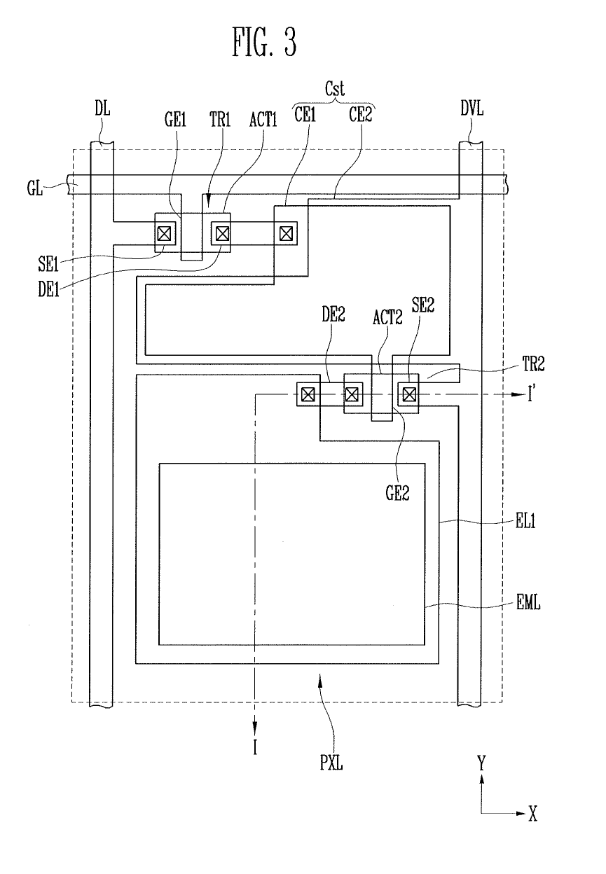

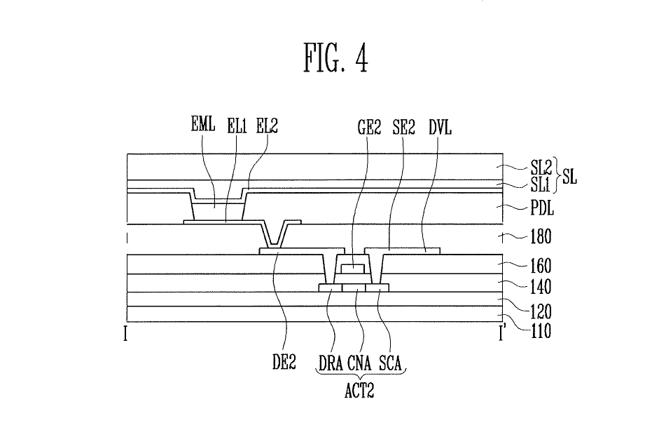

FIG. 3 illustrates a layout embodiment of a pixel, which, for example, may correspond to the pixel PXL illustrated in FIG. 2. FIG. 4 illustrates a sectional view taken along line I-I′ in FIG. 3.

Referring to FIGS. 3 and 4, the display panel 300 may include a substrate 110, a buffer layer 120, signal lines GL and DL, and pixels PXL. The substrate 110 may be made of insulating material such as glass or resin. In one embodiment, the substrate 110 may be made of material having flexibility so as to be bendable or foldable. Examples of the material for the substrate 110 include at least one of the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. Also, the substrate 110 may have a single layer or multilayer structure.

The buffer layer 120 may be on the substrate 110 and include inorganic material such as a silicon oxide, a silicon nitride, and/or a silicon oxynitride. The buffer layer 120 may enhance the smoothness of the upper surface of the substrate 110 or may reduce, minimize, or prevent impurities in the substrate 110 or other layers from permeating transistor TR1 or TR2.

The buffer layer 120 may be doped with an impurity of a first conductivity type or a second conductivity type, e.g., the buffer layer 120 may be doped with a p-type dopant or an n-type dopant. In one embodiment, the buffer layer 120 may be doped with an n-type dopant when the transistor is a PMOS transistor or doped with a p-type dopant when the transistor is an NMOS transistor.

The signal lines GL and DL, the pixels PXL, and other layers or features may be provided on the buffer layer 120. The gate line GL may extend in a first direction (X-axis direction) or a second direction (Y-axis direction). The data line DL may extend in a direction intersecting the gate line GL. A driving voltage line DVL may extend in substantially the same direction as that of the data line DL.

The gate line GL may transmit a scan signal to the first transistor TR1. The data line DL may transmit a data signal to the first transistor TR1. The driving voltage line DVL may provide the first power source ELVDD to the second transistor TR2. The gate line GL may correspond to one of the scan lines S1 to Sp illustrated in FIG. 1. The data line DL may correspond to one of the data lines D1 to Dq illustrated in FIG. 1.

The first transistor TR1 may include a first gate electrode GE1, a first source electrode SE1, and a first drain electrode DEL The first gate electrode GE1 may be coupled to the gate line GL. The first source electrode SE1 may be coupled to the data line DL. The first drain electrode DE1 may be coupled to a gate electrode (e.g., a second gate electrode GE2) of the second transistor TR2.

The first transistor TR1 may transmit a data signal applied to the data line DL to the second transistor TR2 based on a scan signal applied to the gate line GL.

The second transistor TR2 may include a second gate electrode GE2, a second source electrode SE2, and a second drain electrode DE2. The second gate electrode GE2 may be coupled to the first transistor TR1. The second source electrode SE2 may be coupled to the driving voltage line DVL. The second drain electrode DE2 may be coupled to the light-emitting element.

The light-emitting element may include a light-emitting layer EML between a first electrode EL1 and a second electrode EL2. The first electrode EL1 may be coupled to the second drain electrode DE2 of the second transistor TR2. A common voltage may be applied to the second electrode EL2. The light-emitting layer EML may emit light based on an output signal of the second transistor TR2. Light emitted from the light-emitting layer EML may be changed depending on the material of the light-emitting layer and may be color light or white light.

The capacitor Cst may be coupled between the second gate electrode GE2 and the second source electrode SE2 of the second transistor TR2. The capacitor Cst may function to charge and retain a voltage based on a data signal input to the second gate electrode GE2 of the second transistor TR2.

A first active pattern ACT1 and a second active pattern ACT2 may be on the buffer layer 120. For example, the first active pattern ACT1 and the second active pattern ACT2 may be in an area which overlaps a doping area DA of the buffer layer. Each of the first and second active patterns ACT1 and ACT2 may include a channel area CNA between a source area SCA and a drain area DRA.

Each of the first and second active patterns ACT1 and ACT2 may be a semiconductor pattern made, for example, of poly silicon, amorphous silicon, or an oxide semiconductor. Examples of the oxide semiconductor include oxides of titanium (Ti), hafnium (Hf), zirconium (Zr), aluminum (Al), tantalum (Ta), germanium (Ge), zinc (Zn), gallium (Ga), tin (Sn), or indium (In), and complex oxides thereof including a zinc oxide (ZnO), an indium-gallium-zinc oxide (In—Ga—Zn—O), an indium-zinc oxide (In—Zn—O), a zinc-tin oxide (Zn—Sn—O), an indium-gallium oxide (In—Ga—O), an indium-tin oxide (In—Sn—O), an indium-ziroconium oxide (In—Zr—O), an indium-ziroconium-zinc oxide (In—Zr—Zn—O), an indium-ziroconium-tin oxide (In—Zr—Sn—O), an indium-ziroconium-gallium oxide (In—Zr—Ga—O), an indium-aluminum oxide (In—Al—O), an indium-zinc-aluminum oxide (In—Zn—Al—O), an indium-tin-aluminum oxide (In—Sn—Al—O), an indium-aluminum-gallium oxide (In—Al—Ga—O), an indium-tantalum oxide (In—Ta—O), an indium-tantalum-zinc oxide (In—Ta—Zn—O), an indium-tantalum-tin oxide (In—Ta—Sn—O), an indium-tantalum-gallium oxide (In—Ta—Ga—O), an indium-germanium oxide (In—Ge—O), an indium-germanium-zinc oxide (In—Ge—Zn—O), an indium-germanium-tin oxide (In—Ge—Sn—O), an indium-germanium-gallium oxide (In—Ge—Ga—O), a titanum-indium-zinc oxide (Ti—In—Zn—O), and a hafnium-indium-zinc oxide (Hf—In—Zn—O).

The channel area CNA may be an area doped with a dopant of a first doping concentration. Each of the source area SCA and the drain area DRA may be an area doped with a dopant of a second doping concentration greater than the first doping concentration.

Each of the channel area CNA, the source area SCA, and the drain area DRA may have conductivity as a dopant is added thereto. For instance, each of the channel area CNA, the source area SCA, and the drain area DRA may have p-type conductivity when a trivalent dopant such as boron (B) is added thereto, or may have n-type conductivity when a pentavalent dopant such as phosphorus (P), arsenic (As), or antimony (Sb) is added thereto

The channel area CNA, the source area SCA, and the drain area DRA may have the same type of conductivity or different types of conductivity. For example, the channel area CNA, the source area SCA, and the drain area DRA may have the same type of conductivity but different doping concentrations. In one embodiment, each of the source area SCA and the drain area DRA may have a p-type semiconductor and the channel area CNA may have an n-type semiconductor.

A first insulating layer 140 may be on the first and second active pattern ACT1 and ACT2. The first insulating layer 140 may have a single layer or multilayer structure including, for example, a silicon oxide, a silicon nitride, and/or silicon oxynitride.

The first gate electrode GE1 may be coupled with the gate line GL. The second gate electrode GE2 may be on the first insulating layer 140. The gate line GL, the first gate electrode GE1, and the second gate electrode GE2 may be made of metal, such as but not limited to molybdenum (Mo) or at least one of gold (Au), silver (Ag), aluminum (Al), chrome (Cr), titanium (Ti), nickel (Ni), neodymium (Nd), and copper (Cu), or an alloy of the metals.

Each of the gate line GL, the first gate electrode GE1 and the second gate electrode GE2 may have a single layer structure, or a multilayer structure formed by stacking two or more materials of metals and alloys.

The first gate electrode GE1 and the second gate electrode GE2 may respectively cover areas corresponding to the channel areas CNA of the first and second active patterns ACT1 and ACT2.

A second insulating layer 160 may be on the first and second gate electrodes GE1 and GE2 and cover the first and second gate electrodes GE1 and GE2. The second insulating layer 160 may include inorganic material, e.g., a silicon oxide, a silicon nitride, and/or a silicon oxynitride.

The first source electrode SE1, the first drain electrode DE1, the second source electrode SE2, and the second drain electrode DE2 may be on the second insulating layer 160. The first source electrode SE1 and the first drain electrode DE1 may respectively contact with the source area and the drain area of the first active pattern ACT1 through contact holes in the first and second insulating layers 140 and 160.

The second source electrode SE2 and the second drain electrode DE2 may respectively contact with the source area SCA and the drain area DRA of the second active pattern ACT2 through contact holes in the first and second insulating layers 140 and 160.

The source electrodes SE1 and SE2, the drain electrodes DE1 and DE2, and the driving voltage line DVL that are on the second insulating layer 160 may be made of metal. For example, each of the source electrodes SE1 and SE2, the drain electrodes DE1 and DE2, and the driving voltage line DVL may be made of at least one of gold (Au), silver (Ag), aluminum (Al), molybdenum (Mo), chrome (Cr), titanium (Ti), nickel (Ni), neodymium (Nd), copper (Cu), or an alloy of the metals.

A portion of the second gate electrode GE2 and a portion of the driving voltage line DVL may be respectively a first capacitor electrode CE1 and a second capacitor electrode CE2 of the capacitor Cst, with the second insulating layer 160 therebetween.

A third insulating layer 180 may be on the first source electrode SE1, the first drain electrode DE1, the second source electrode SE2, and the second drain electrode DE2. The third insulating layer 180 may function as a protective layer for protecting the transistors TR1 and TR2 and/or as a planarization layer for planarizing an upper surface thereof.

The first electrode EL1 may be on the third insulating layer 180 and serve as an anode of the light-emitting element. The first electrode EL1 may be coupled to the second drain electrode DE2 of the second transistor TR2 through a contact hole in the third insulating layer 180. The first electrode EL1 may serve as a cathode, but in the following embodiment an example is described wherein it is used as an anode.

The first electrode EL1 may include transparent conductive material such as an indium tin oxide (ITO), an indium zinc oxide (IZO), a zinc oxide (ZnO) or an indium oxide (In₂O₃), or reflective metal such as lithium (Li), calcium (Ca), lithium fluoride/calcium (LiF/Ca), lithium fluoride/aluminum (LiF/Al), aluminum (Al), silver (Ag), magnesium (Mg), or gold (Au).

A pixel defining layer PDL is on the first electrode EL1 and defines a pixel area corresponding to each pixel PXL. The pixel defining layer PDL may include an opening through which the upper surface of the first electrode EL1 is exposed. For example, the pixel defining layer PDL may define the pixel area corresponding to each pixel.

The light-emitting layer EML is in the opening of the pixel defining layer PDL.

The second electrode EL2 may be on the pixel defining layer PDL and the light-emitting layer EML. The second electrode EL2 may be formed of a metal layer (e.g., made of Ag, Mg, Al, Pt, Pd, Au, Ni, Nd, Ir, and/or Cr) and/or a transparent conductive layer, e.g., made of an indium tin oxide (ITO), an indium zinc oxide (IZO), a zinc oxide (ZnO), or an indium tin zinc oxide (ITZO). In an embodiment, the second electrode EL2 may have a multilayer structure of two or more layers including a thin metal layer. The second electrode EL2 may include, for example, a triple-layer structure of ITO/Ag/ITO.

An encapsulation layer SL may be on and cover the second electrode EL2. The encapsulation layer SL may have a single layer or multi-layer structure.

In an embodiment, the encapsulation layer SL may include a first encapsulation layer SL1 and a second encapsulation layer SL2 including different materials. For example, the first encapsulation layer SL1 may be made of organic material and the second encapsulation layer SL2 may be made of inorganic material. The encapsulation layer SL may have a different structure or may include a different material in another embodiment. For example, the encapsulation layer SL may include a plurality of organic material layers and a plurality of inorganic material layers that are alternately stacked.

The structure of the pixel PXL illustrated in FIGS. 3 and 4 may be different in another embodiment. For example, the numbers of transistors and/or capacitors in the pixel PXL may be different from those discussed above. Also, the structures of transistors and/or capacitors in the pixel PXL may also be different.

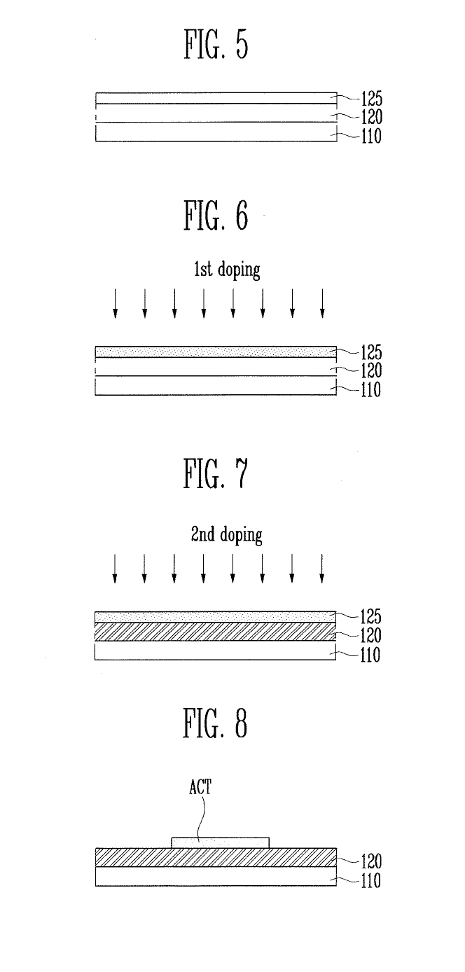

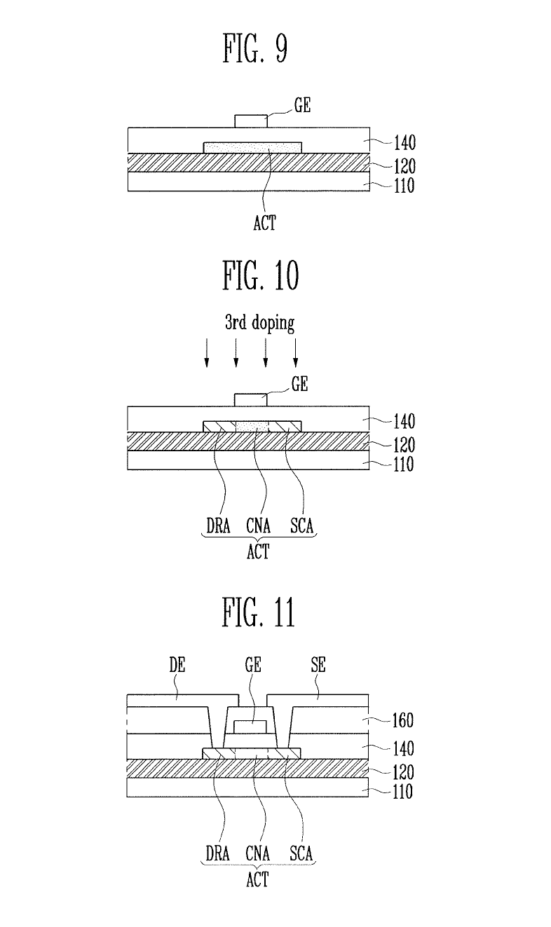

FIGS. 5 to 10 illustrate various stages of an embodiment of a method for manufacturing a transistor. FIG. 11 illustrates an embodiment of a transistor, e.g., a PMOS. The transistor may be an NMOS transistor in another embodiment.

Referring to FIG. 5, the buffer layer 120 and the semiconductor layer 125 may be sequentially formed on the substrate 110. The buffer layer 120 may be formed of insulating material and deposited by various deposition methods. In FIG. 5, the semiconductor layer 125 may be formed of a semiconductor including amorphous silicon or crystalline silicon without an artificial doping process, and may be processed by various deposition methods.

Referring to FIG. 6, a first doping process is performed on the semiconductor layer 125. During the first doping process, an impurity of a first conductivity type (e.g., boron (B) of p-type dopants) may be implanted in the semiconductor layer 125. The semiconductor layer 125 may have a first doping concentration through the first doping process. The first doping process may be performed, for example, by an ion implantation method in which ions are accelerated and impacted into a solid. During the first doping process, impurities of the first conductivity type accelerated by a first energy may be implanted in the semiconductor layer 125.

Referring to FIG. 7, a second doping process is performed after the first doping process has been performed. The second doping process may be performed for the buffer layer 120. An impurity of a second conductivity type different from the first conductivity type may be implanted in the buffer layer 120. For example, when the semiconductor layer 125 (e.g., active pattern) has been doped with p-type dopant ions during the first doping process, the buffer layer 120 may be doped with n-type dopant ions. When the semiconductor layer 125 (e.g., active pattern) has been doped with n-type dopant ions during the first doping process, buffer layer 120 may be doped with p-type dopant ions.

In this embodiment, because p-type dopant ions (e.g., boron (B)) have been implanted in the semiconductor layer 125 during the first doping process, as described with reference to FIG. 6, n-type dopant ions (e.g., phosphorus (P)) may be implanted in the buffer layer 120 as illustrated in FIG. 7.

During the second doping process, the impurities to be implanted in the semiconductor 125 may be accelerated with second energy greater than the first energy. As a result, the impurities may be implanted in the buffer layer 120 via the semiconductor layer 125.

After the second doping process, an annealing process may be performed, for example, by irradiating a laser onto the buffer layer 120 and the semiconductor layer 125 over or under the substrate 110. In an embodiment, an excimer laser may be used. The excimer laser is a gas laser which uses molecules (e.g., ArF, KrF, XeCl, etc.) that are called excimer. An excimer laser generates a beam having a short wavelength and high power output.

During the annealing process, amorphous silicon of the semiconductor layer 125 may be crystallized, defects generated in the semiconductor layer 125 or the buffer layer 120 may be removed, or the dopant ions may be activated.

A method for crystallizing amorphous silicon may include not only a method using the above-mentioned excimer laser, but also a rapid thermal annealing (RTA) method, a solid phase crystallization (SPC) method, a metal induced crystallization (MIC) method, a metal induced lateral crystallization (MILC) method, a sequential lateral solidification (SLS) method, and/or other methods.

Referring to FIG. 8, the active pattern ACT may be formed after the second doping process has been performed. The active pattern ACT may be formed by patterning the semiconductor layer 125 through a mask process.

Referring to FIG. 9, after the active pattern ACT has been formed, the first insulating layer 140 may be formed to cover the active pattern ACT on the buffer layer 120. The first insulating layer 140 may be formed to have a single layer or multilayer structure including, for example, silicon oxide, silicon nitride, and/or silicon oxynitride. The first insulating layer 140 may be formed by various deposition methods, e.g., a chemical vapour deposition (CVD) method and a plasma enhanced chemical vapor deposition (PECVD).

Thereafter, a gate electrode GE may be formed on the first insulating layer 140, for example, by forming a first conductive layer on the entire surface of the first insulating layer 140 and patterning the first conductive layer through a mask process. The first conductive layer may be formed, for example, by a sputtering method.

The mask process may be performed in such a way that a series of processes (e.g., including a developing process, an etching process, and a stripping process or an aching process) are performed after a process of applying photoresist and a process of selectively exposing the photoresist using a mask have been performed.

Referring to FIG. 10, a third doping process is performed to implant an impurity of the first conductivity type in the active pattern. The gate electrode GE functions as a mask, and the impurity is implanted in an area of the active pattern other than an area thereof that overlaps the gate electrode GE, e.g., the channel area CNA. As a result, the source area SCA and the drain area DRA may be formed.

The source area SCA and the drain area DRA may have a second doping concentration higher than the first doping concentration through the third doping process. The impurity to be implanted in the source area SCA and the drain area DRA may be the same as the impurity to be implanted in the active pattern ACT during the first doping process.

An area of the active pattern ACT that overlaps the gate electrode GE may become the channel area CNA. For example, the channel area CNA may be between the source area SCA and the drain area DRA. After the third doping process has been performed, an activation process may be performed to activate the dopant.

FIG. 11 illustrates an embodiment of a transistor, which, for example, may be the transistor according to the embodiment illustrated in FIGS. 5 to 10. Referring to FIG. 11, the second insulating layer 160 may be on the gate electrode GE. The second insulating layer 160 may include inorganic material, e.g., a silicon oxide, a silicon nitride, and/or a silicon oxynitride. The second insulating layer 160 may be formed by various deposition methods, e.g., a chemical vapor deposition (CVD) method and a plasma enhanced chemical vapor deposition (PECVD) method.

A source electrode SE and a drain electrode DE may be on the second insulating layer 160. The source electrode SE and the drain electrode DE may be formed, for example, by forming a second conductive layer on the entire surface of the second insulating layer 160 and patterning the second conductive layer through a mask process. The second conductive layer may be formed, for example, by a sputtering method.

The source electrode SE may contact with the source area SCA through a contact hole in the first and second insulating layers 140 and 160. The drain electrode DE may contact with the drain area DRA through a contact hole in the first and second insulating layers 140 and 160. Such a transistor may be employed in a pixel PXL in accordance with any of the embodiments described herein.

The stability of a transistor may be improved by improving hysteresis characteristics. Hysteresis characteristics may be improved by increasing a carrier concentration of the channel area. Carrier concentration of the channel area CNA may be increased by increasing the first doping concentration during the first doping process.

However, even though hysteresis characteristics may be improved by increasing the carrier concentration of the channel area, it may be difficult to control the threshold voltage value of the transistor to equal a desired value. This is because the threshold voltage value of the transistor may be moved. For example, if the amount of boron ions to be implanted in the channel area is increased to improve the hysteresis characteristics when the PMOS transistor is manufactured, the threshold voltage value of the transistor may move in a positive (+) direction.

However, in accordance with one or more embodiments, the threshold voltage value, which is moved in the positive direction depending on the carrier concentration of the channel area CAN, may be moved in a negative direction by doping the buffer layer 120 with n-type dopant ions. Table 1 shows results of example experiments performed on a variation of the threshold voltage value of a transistor depending on the doping concentration of the buffer layer 120.

TABLE 1

| | Comparative | Embodiment | Embodiment | Embodiment |
|---|---|---|---|---|
| Items | Example 1 | 1 | 2 | 3 |
| Dose of | 4 × 10¹¹/cm² | 4 × 10¹¹/cm² | 4 × 10¹¹/cm² | 4 × 10¹¹/cm² |
| Channel Area | | | | |
| Dose of Buffer | — | 4 × 10¹¹/cm² | 4 × 10¹²/cm² | 4 × 10¹³/cm² |
| Layer | | | | |
| Threshold | −2.13 V | −2.33 V | −3.55 V | −9.33 V |
| Voltage of | | | | |
| Transistor | | | | |

As shown in Table 1, the transistors according to comparative example 1 and embodiments 1 to 3 have the same size. The channel areas of the transistors according to comparative example 1, and embodiments 1 to 3 have been doped with boron ions, and have the same dose of 4×10¹¹/cm². The boron ions have been accelerated at 10 KeV and implanted in the channel area.

The transistor of comparative example 1 is a transistor in which the buffer layer 120 has not been processed through a separate doping process.

The transistor of embodiment 1 is a transistor in which the buffer layer 120 has a dose of 4×10¹¹/cm². The transistor of embodiment 2 is a transistor in which the buffer layer 120 has a dose of 4×10¹²/cm². The transistor of embodiment 3 is a transistor in which the buffer layer 120 has a dose of 4×10¹³/cm². The buffer layers 120 of embodiments 1 to 3 have been doped with phosphorus ions in such a way that the phosphorus ions are accelerated at 70 KeV and implanted in the buffer layers 120.

As shown in Table 1, the threshold voltage values of embodiments 1 to 3 are less than the threshold voltage value of comparative example 1. In other words, it may be understood that when the buffer layer 120 is doped with an n-type dopant, the threshold voltage value is moved in a negative (−) direction.

Referring to embodiments 1 to 3, it may be understood that as the dose of the buffer layer 120 is increased, a change in the threshold voltage value is increased. In other words, according to one or more embodiments, the threshold voltage of the transistor may be adjusted by adjusting the doping concentration of the channel area CNA and the doping concentration of the buffer layer 120. As a result, hysteresis characteristics of the transistor may be improved.

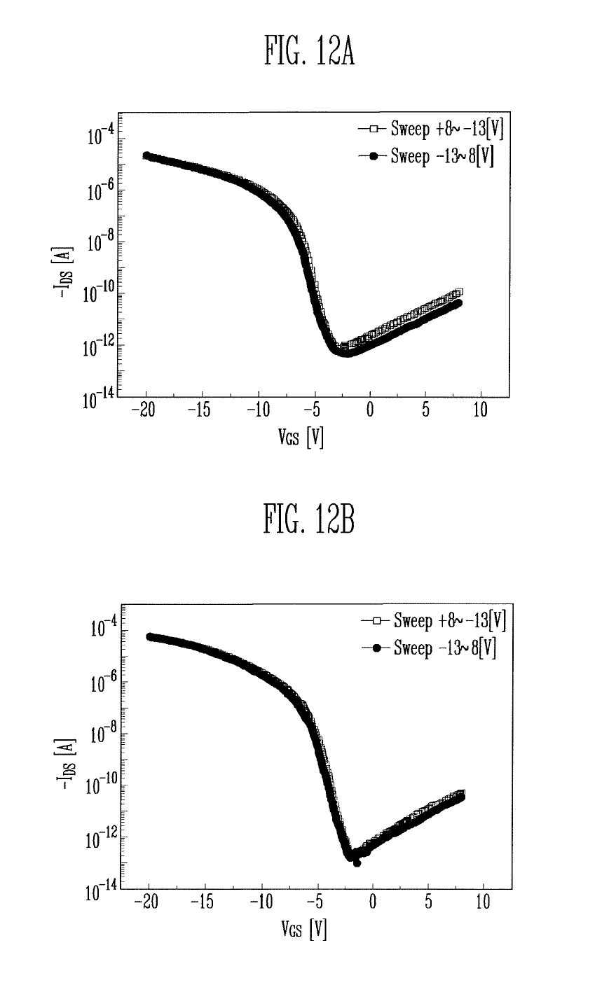

FIGS. 12A and 12B are graphs illustrating examples of differences in hysteresis characteristics of the transistor depending on whether or not a buffer layer is doped. FIG. 12A illustrates an example of hysteresis characteristics of a transistor (hereinafter, referred to as comparative example 2) in which a buffer layer is not processed through a separate doping process. FIG. 12B illustrates hysteresis characteristics of a transistor (hereinafter, referred to as embodiment 4) having a doped buffer layer.

The transistors according to comparative example 2 and embodiment 4 have the same size. The channel area CNA of the transistor according to comparative example 2 has been doped with boron ions and has a dose of 3×10¹²/cm². The channel area CNA of the transistor according to embodiment 4 has been doped with boron ions and has a dose of 6×10¹²/cm². The boron ions have been accelerated at 10 KeV and implanted in the channel area.

The buffer layer 120 of the transistor according to comparative example 2 has not been processed through a separate doping process. The buffer layer 120 of the transistor according to embodiment 4 has been doped with phosphorus ions and has a dose of 4×10¹³/cm². The phosphorus ions were accelerated at 80 KeV and implanted in the buffer layer 120.

The hysteresis characteristics may be checked by comparing an output (e.g., a measured drain-source current value of the transistor) measured while increasing the gate-source voltage of the transistor and an output (e.g., a measured drain-source current value of the transistor) measured while reducing the gate-source voltage of the transistor. The more the two output values are similar to each other, the more excellent the hysteresis characteristics are.

Comparing FIGS. 12A and 12B, it may be determined that the hysteresis characteristics of the transistor of embodiment 4 is more excellent than that of the transistor of comparative example 2. Thus, the hysteresis characteristics of the transistor may be improved by doping the buffer layer 120.

In accordance with one or more embodiments, a transistor is provided with improved hysteresis characteristics and a desired threshold voltage value.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, various changes in form and details may be made without departing from the spirit and scope of the embodiments set forth in the claims.

What is claimed is:

1. A transistor, comprising:
a buffer layer on a substrate and doped with an impurity;
an active pattern on the buffer layer and including a channel area between a source area and a drain area;
a first insulating layer on the active pattern;
a gate electrode on the first insulating layer and overlapping the channel area;
a source electrode insulated from the gate electrode and electrically coupled with the source area; and
a drain electrode insulated from the gate electrode and electrically coupled with the drain area.

2. The transistor as claimed in claim 1, wherein:
the active pattern is doped with an impurity of a first conductivity type, and
the buffer layer is doped with an impurity of a second conductivity type opposite to the first conductivity type.

3. The transistor as claimed in claim 2, wherein a change in a threshold voltage of the transistor is increases as a dose of the impurity of the first conductivity type increases.

4. The transistor as claimed in claim 2, wherein a doping concentration of each of the source area and the drain area is greater than a doping concentration of the channel area.

5. A method for manufacturing a transistor, the method comprising:
forming a buffer layer and a semiconductor layer on a substrate;
performing a first doping process of doping the semiconductor layer with a first impurity;
performing a second doping process of doping the buffer layer with a second impurity;
forming an active pattern by patterning the semiconductor layer;
forming a first insulating layer on the active pattern;
forming a gate electrode on the first insulating layer; and
performing a third doping process of forming a source area and a drain area by doping a portion of the active pattern with a third impurity using the gate electrode as a mask.

6. The method as claimed in claim 5, wherein the buffer layer is between the substrate and the active pattern.

7. The method as claimed in claim 5, wherein:
the first impurity is of a first conductivity type, and
the first doping process includes accelerating the first impurity with a first energy to be implanted in the active pattern.

8. The method as claimed in claim 7, wherein:
the second impurity is accelerated with a second energy to be implanted in the buffer layer, and
the second energy is greater than the first energy.

9. The method as claimed in claim 8, wherein the second impurity is of a second conductivity type opposite to the first conductivity type.

10. The method as claimed in claim 5, further comprising:
annealing the semiconductor layer and the buffer layer after the second doping process.

11. The method as claimed in claim 10, wherein the annealing is performed using an excimer laser.

12. The method as claimed in claim 5, further comprising:
forming a source electrode coupled to the source area and a drain electrode coupled to the drain area.

13. The method as claimed in claim 5, wherein a dose of the third impurity is greater than a dose of an impurity of a channel area between the source area and the drain area.

14. A display device, comprising:
a display panel including a plurality of pixels on a substrate,
wherein each of the pixels includes an electrode, a display layer on the electrode, and a transistor coupled to the electrode, and
wherein the transistor includes:
a buffer layer on the substrate and doped with an impurity;
an active pattern on the buffer layer and including a channel area between a source area and a drain area;
a gate electrode insulated from the active pattern and overlapping the channel area; and
a source electrode and a drain electrode insulated from the gate electrode and respectively electrically coupled to the source area and the drain area.

15. The display device as claimed in claim 14, wherein:
the channel area is doped with an impurity of a first conductivity type, and
the buffer layer is doped with an impurity of a second conductivity type opposite to the first conductivity type.

16. The display device as claimed in claim 15, wherein:
the transistor is a PMOS transistor, and
the impurity of the first conductivity type is a p-type impurity.

17. A transistor, comprising:
a buffer layer doped with an impurity of a first conductivity type; and
an active pattern on the buffer layer and doped with an impurity of a second conductivity type, wherein the active pattern includes a channel area between a source area and a drain area and wherein each of the source area and drain have a first doping concentration of the impurity of the second conductivity type greater than a second doping concentration of the impurity of the second conductivity type of the channel area.

18. The transistor as claimed in claim 17, a threshold voltage of the transistor is proportional to the first doping concentration of the impurity of the second conductivity type.

19. The transistor as claimed in claim 17, wherein:
the transistor is a PMOS transistor, and
the impurity of the first conductivity type is a p-type impurity.

20. The transistor as claimed in claim 17, wherein a doping concentration of the impurity of the first conductivity type in the buffer layer is equal to or greater than at least one of the first doping concentration and the second doping concentration.
